(19) United States
(12) Patent Application Publication
(10) Pub. No.: US 2026/0297729 A1
(43) Pub. Date: Oct. 1, 2026

(54) METHOD OF FORMING A STRUCTURE USING SELECTIVE DEPOSITION ON A METAL SURFACE

(71) Applicant: ASM IP Holding B.V., Almere (NL)

(72) Inventors: YoungChol Byun, Tempe, AZ (US); Sang Ho Yu, Cupertino, CA (US); Chad Russell Lunceford, Phoenix, AZ (US); Richard Nile, Gilbert, AZ (US); Jonathan Bakke, Phoenix, AZ (US); Kranthi Kumar Vaidyula, Chandler, AZ (US); Holger Saare, Leuven (BE); Sukanya Datta, Phoenix, AZ (US); Aditya Deshpande, Tempe, AZ (US)

(21) Appl. No.: 19/629,057

(22) Filed: Mar. 26, 2026

Related U.S. Application Data
(60) Provisional application No. 63/780,902, filed on Mar. 31, 2025.

(51) Int. Cl. C23C 16/02; C23C 16/04; C23C 16/44; C23C 16/455

(52) U.S. Cl. CPC C23C 16/0272; C23C 16/04; C23C 16/4408; C23C 16/45553

(57) ABSTRACT

Methods for forming a structure with selective deposition on a metal surface are disclosed. An exemplary method includes providing a substrate in a reaction chamber, optionally performing a pre-treatment process on the metal surface, performing a growth promotion treatment, and depositing a film on or overlying the metal surface. An exemplary growth promotion treatment includes pulsing a boron-containing precursor and performing a purge.

### CROSS-REFERENCE TO RELATED APPLICATIONS

This application is a nonprovisional of, and claims priority to and the benefit of, U.S. Provisional Patent Application No. 63/780,902, filed Mar. 31, 2025 and entitled “METHOD OF FORMING A STRUCTURE USING SELECTIVE DEPOSITION ON A METAL SURFACE,” which is hereby incorporated by reference herein.

### FIELD

The disclosure generally relates to methods of and apparatuses suitable for forming electronic devices. More particularly, examples of the disclosure relate to a method for forming a structure with a selective deposition of a film on a metal surface and to a substrate processing apparatus for forming the structure.

### BACKGROUND

Conductive metal layers, such as copper layers, are used in a wide variety of electronic devices, such as semiconductor devices. However, conductive metal layers, such as copper layers, are easily contaminated and easily corroded. Additionally, some conductive metal layers, such as copper layers, can lead to diffusion and electromigration of the metal to other films. Conventional methods of deposition of films on conductive metal layers that prevent contamination or corrosion of the metal layer and diffusion of the metal can be complicated, costly, and involve multiple processes. Accordingly, there exists a desire for improved methods of and apparatuses for depositing films on conductive metal surfaces that are simpler, cheaper, and/or require less steps, while preventing contamination corrosion, and diffusion.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

Various examples described herein relate to methods for forming a structure. Exemplary methods include selectively depositing films on a metal surface. As set forth below, methods described herein may be used in the fabrication of electronic devices, such as semiconductor devices. As set forth in more detail below, exemplary methods include use of a growth promotion treatment on a metal surface, and subsequently selectively depositing a film on the metal surface.

According to one or more embodiments, an exemplary method includes providing a substrate in a reaction chamber, where the substrate includes a metal surface on at least part of a surface of the substrate. In some embodiments, the substrate surface includes one or more features, each feature including a bottom surface and a sidewall surface. In accordance with examples, the bottom surface is or includes the metal surface. The exemplary method continues with performing a growth promotion treatment. Exemplary growth promotion treatments include pulsing a boron-containing precursor to the reaction chamber and performing a purge. In some embodiments, the growth promotion treatment includes depositing a growth promotion layer (e.g., directly) on the metal surface. The exemplary method continues with (e.g., selectively) depositing a film on the metal surface. In some embodiments, the film may be deposited directly on the growth promotion layer. In some embodiments, depositing the film may remove at least a portion of the growth promotion layer.

In accordance with examples of the disclosure, the growth promotion treatment may include repeating the step of pulsing a boron-containing precursor to the reaction chamber. In some embodiments, a purge is performed after every pulse of the boron-containing precursor. In accordance with examples of the disclosure, the boron-containing precursor includes boron and hydrogen. By way of examples, the boron-containing precursor may be or include borane, diborane, triborane, triethylborane, trimethylborane, borazine, or borazane. The boron-containing precursor may bond with the metal surface to form boron-metal bonds. The boron-metal bonds may prevent other species from contaminated or damaging the metal surface.

The film may be deposited using a chemical vapor deposition process or a cyclical deposition process. In some embodiments, the film is deposited using a halide precursor. In such embodiments, a halide component from the halide precursor may react with a boron component to form a boron halide that may be removed from the metal surface and/or the reaction chamber.

In accordance with further examples of the disclosure, a device is formed using a method and/or include a structure as described herein.

In accordance with yet further exemplary embodiments of the disclosure, a system is provided for performing a method and/or for forming a structure as described herein.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWINGS

FIG. 1 illustrates a method for forming a structure in accordance with one or more embodiments of the disclosure;

FIG. 2 illustrates a feature on a substrate according with one or more examples of the disclosure;

FIG. 3 illustrates a method for a growth promotion treatment in accordance with one or more embodiments of the disclosure;

FIG. 4 illustrates a method for depositing a film in accordance with one or more embodiments of the disclosure;

FIG. 5 illustrates an example of a substrate processing apparatus in accordance with one or more examples of the disclosure;

FIG. 6 illustrates an example of a structure that can form part of a device in accordance with one or more examples of the disclosure; and

FIG. 7 illustrates another example of a structure that can form part of a device in accordance with one or more examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods, structures, devices, and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As used herein, the term “and/or” includes any and all combinations of one or more of the associated listed items. Unless otherwise noted, expressions such as “at least one of,” when preceding a list of elements, modify the entire list of elements and do not necessarily modify the individual elements of the list.

As used herein, the singular forms “a,” “an,” and “the” are intended to include the singular and plural forms as well, unless the context indicates otherwise.

As used herein, the term “substrate” can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as Group III-V or Group II-VI semiconductors, and can include one or more layers overlying or underlying the bulk material. By way of example, a substrate can include silicon or silicon germanium, and may include a metal surface.

The terms “precursor” and “reactant” can refer to molecules or compounds that participate in a chemical reaction that produces a layer or deposited material. A precursor typically contains portions that are at least partly incorporated into a layer. Such resulting portions may be deposited on a substrate to form a film as disclosed herein. A reactant may be a compound that is incorporated into the layer or that is not incorporated into the resulting layer to a significant extent. In some cases, the term reactant can be used interchangeably with the term precursor.

As used herein, a “metal precursor” includes a gas or a material that can become gaseous and that can be represented by a chemical formula that includes one or more metals.

In some embodiments, “film” refers to a layer extending in a direction perpendicular to a thickness direction. In some embodiments, “layer” refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. The layer or film can be continuous—or not. Further, a single film or layer can be formed using one or more deposition cycles.

As used herein, the term “purge” can refer to a procedure in which an inert or substantially inert gas is provided to a reaction chamber in between two pulses of gases that might otherwise react with each other. For example, a purge, e.g., using an inert gas, such as a noble gas, may be provided between a precursor pulse and a reactant pulse to reduce gas phase interactions between the precursor and the reactant that might otherwise occur. It shall be understood that a purge can be affected either in time or in space, or both. For example, in the case of temporal purges, a purge step can be used, e.g., in the temporal sequence of providing a precursor to a reaction chamber, providing a purge gas to the reaction chamber, and providing a reactant or another precursor to the reaction chamber, wherein the substrate on which a layer is deposited does not move. In the case of spatial purges, a purge step can take the following form: moving a substrate from a first location to which a precursor is (e.g., continually) supplied, through a purge gas curtain, to a second location to which a reactant or other precursor is (e.g., continually) supplied.

As used herein, the term “structure” can refer to a partially or completely fabricated device structure. By way of examples, a structure can be a substrate or include a substrate with one or more layers and/or features formed thereon.

As used herein, the term “overlying” can refer to two films in (e.g., direct) contact with each other.

As used herein, the term “cyclical deposition process” or “cyclic deposition process” can refer to a vapor deposition process in which deposition cycles, typically a plurality of consecutive deposition cycles, are conducted in a process chamber. Cyclic deposition processes can include, for example, cyclic chemical vapor deposition (CCVD) and/or atomic layer deposition (ALD) processes.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. For example, values of variables may include +/−20%, or +/−10%, or +/−5%, or +/−1%, or +/−0% of the value of the listed variable. Further, in this disclosure, the terms “comprising,” “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

A carrier and/or inert gas can be (e.g., continuously) co-flowed throughout any steps or sub-steps of any methods described herein. By way of example, a carrier and/or an inert gas can be one or more of helium, argon, or nitrogen.

Various steps of methods described herein can be performed within a single reaction chamber or can be performed in multiple reaction chambers, such as reaction chambers of a cluster tool. In some embodiments, the methods may take place in a single reaction space. In some embodiments, one or more steps or substeps of methods described herein may take place in different reaction spaces and/or a different reaction chambers.

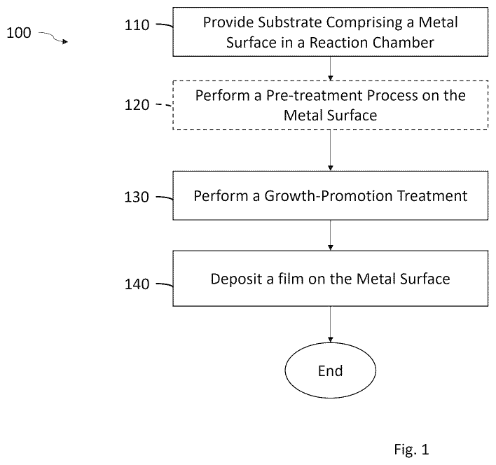

FIG. 1 illustrates a method 100 for forming a structure in accordance with exemplary embodiments of the disclosure. Method 100 includes providing a substrate comprising a metal surface within a reaction chamber (step 110), optionally performing a pre-treatment process on the metal surface (step 120), performing a growth promotion treatment (step 130), and (e.g., selectively) depositing a film on the metal surface (step 140).

During step 110, a substrate is provided into a reaction space in a reaction chamber. In accordance with examples of the disclosure, the reaction chamber can form part of a chemical vapor deposition reactor, such as a chemical vapor deposition (CVD) reactor, an atomic layer deposition (ALD) reactor, or the like.

During step 110, the substrate can be brought to a desired temperature and/or the reaction space can be brought to a desired pressure, such as a temperature and/or pressure suitable for subsequent steps. By way of examples, a temperature (e.g., of a substrate, a substrate support, or an environment) within a reaction space can be between about 0° C. and about 500° C. or between about 250° C. and about 425° C. By way of examples, a pressure within a reaction space can be less than 760 torr, or between about 1 torr and 500 torr, or between about 1 torr and about 100 torr.

The substrate provided during step 110 comprises a metal surface. In some embodiments, the metal surface is metallic. In some embodiments, the metal surface comprises one or more of copper, cobalt, nickel, zinc, ruthenium, or molybdenum. In some embodiments, the substrate comprises a first surface comprising a metal surface and a second surface comprising a dielectric surface, such as silicon oxide. In some embodiments, the second surface comprises a low-k dielectric material.

In some embodiments, the substrate may comprise one or more features. The features may be gaps, trenches, or the like. The one or more features may have an aspect ratio greater than 1, or greater than 10, or between about 5 and about 25. The one or more features may have a depth greater than 10 nm, or greater than 30 nm, or between about 10 nm and 100 nm. Additionally or alternatively, the one or more features may have a width between about 5 nm and about 100 nm, or between about 10 nm and about 50 nm. In some embodiments, the one or more features may comprise a bottom surface, a sidewall surface, and a top surface. In some embodiments, the bottom surface comprises the metal surface. In some embodiments, the sidewall surface and/or the top surface comprises the dielectric surface, such as a low-k material.

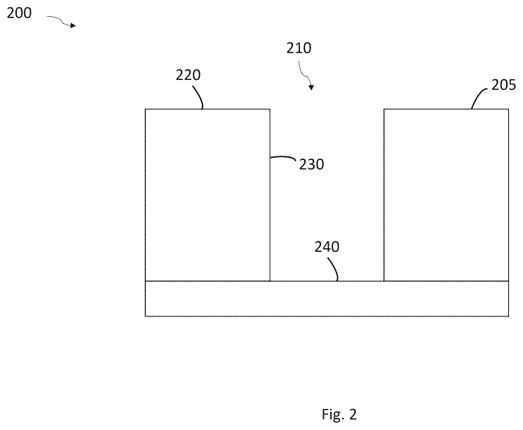

FIG. 2 illustrates a substrate 200 comprising a surface 205 having feature 210 formed thereon. The surface 205 of the substrate 200 provided during step 110 typically includes a plurality of features 210. The features 210 may be gaps, trenches, or the like. The one or more features 210 may have an aspect ratio greater than 1, or greater than 10, or between about 5 and about 25. The one or more features 210 may have a depth greater than 10 nm, or greater than 30 nm, or between about 10nm and 100 nm. Additionally or alternatively, the one or more features may have a width between about 5 nm and about 100 nm, or between about 10 nm and about 50 nm, or between about 25 nm and about 35 nm. Feature 210 comprises a top surface 220, a sidewall surface 230, and a bottom surface 240. In some embodiments, the sidewall surface 230 comprises a dielectric surface, as described herein. In some embodiments, the bottom surface 240 comprises a metal surface, as described herein. In some embodiments, the top surface 220 comprises a dielectric surface. Top surface 220 may coincide with surface 205.

Turning back to FIG. 1, the method 100 continues with optionally performing a pre-treatment process on the metal surface (step 120). In accordance with examples of the disclosure, the pre-treatment process may remove impurities, such as oxygen, from the metal surface. In some embodiments, the pre-treatment process comprises exposing the metal surface to a hydrogen plasma or species generated by a hydrogen plasma. The hydrogen plasma may be a direct plasma or a remote plasma. In some embodiments, the hydrogen plasma is formed from a hydrogen-containing gas, such as hydrogen (H₂) and optionally, an inert gas.

The method 100 continues with performing a growth promotion treatment (step 130). The growth promotion treatment comprises pulsing a boron-containing precursor. In some embodiments, the boron-containing precursor comprises boron and hydrogen. By way of examples, the boron-containing precursor may be or include borane, diborane, triborane, triethylborane, trimethylborane, borazine, and borazane. In some embodiments, the boron-containing precursor comprises a substituted borane. In some embodiments, the substituted borane has a formula of BₓR_{y}, where x is from 1 to 3, y is 2 times x, and each R is independent selected from H and C1-C3 alkyl groups. In some embodiments, performing the growth promotion treatment forms a growth promotion layer on the metal surface. The growth promotion layer comprises boron. In some embodiments, the growth promotion layer comprises boron-metal bonds. In some embodiments, a thickness of the growth promotion layer may be between about 5 Angstroms and about 60 Angstroms, or between about 10 Angstroms and about 50 Angstroms, or between about 20 Angstroms and about 40 Angstroms. Not to be bound by theory, it is thought that precursors used in subsequent steps may react with boron on the metal surface to selectively nucleate a subsequently deposited layer. Further, the use of boron may be advantageous as the boron may form volatile compounds with components of precursors and be removed in the deposition process.

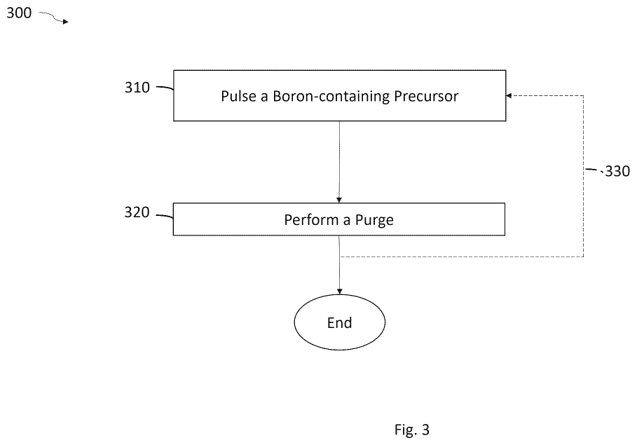

FIG. 3 illustrates a method 300 suitable for step 130 in FIG. 1. Method 300 comprises pulsing a boron-containing precursor 310, performing a purge 320, and optionally repeating the steps one or more times (loop 330). Each sub-step 310-320 of method 300 may be performed once or a plurality of times before proceeding to the next step. In some embodiments, a purge, such as purge 320, is performed after pulse of the boron-containing precursor 310.

In some embodiments, hydrogen (H₂) is co-flowed with the boron-containing precursor.

A duration of providing the pulse of the boron-containing precursor to the reaction chamber during each cycle can be between about 0.1 seconds and about 60 seconds, between about 0.1 seconds and about 10 seconds, or between about 0.5 seconds and about 5 seconds, or between about 2 seconds and 4 seconds. A flowrate of the boron-containing precursor to the reaction chamber can be less than 1000 sccm, or less than 500 sccm, or less than 100 sccm, or less than 10 sccm, or even less than 1 sccm or range from about 1 to 2000 sccm, from about 5 to 1000 sccm, or from about 10 to 500 sccm.

Turning back to FIG. 1, the method 100 continues with (e.g., selectively) depositing a film on the metal surface. In some embodiments, the film is selectively deposited on the metal surface relative to the dielectric surface. Depositing a film on the metal surface may comprise a cyclical deposition process. In some embodiments, the film comprises a conductive material. In some embodiments, the film comprises a metal. In some embodiments, the film is metallic. In some embodiments, the film is an elemental metal or a metal alloy. In some embodiments, the film is or includes molybdenum or copper.

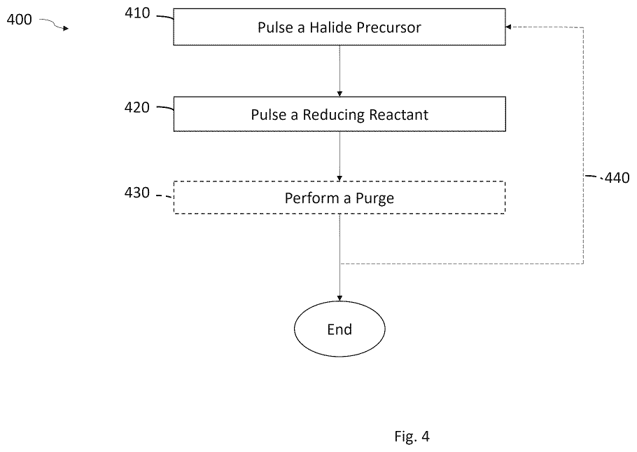

FIG. 4 illustrates a method 400 suitable for step 140 in FIG. 1. Method 400 comprises pulsing a halide precursor 410, pulsing a reducing reactant 420, optionally performing a purge 430, and optionally repeating the steps one or more times (loop 440). Sub-steps 410-420 of method 400 may be performed in any order. Each sub-step 410-430 of method 400 may be performed once or a plurality of times before proceeding to the next step. In some embodiments, a purge, such as purge 430, is performed after a pulse of the halide precursor 410 and/or a pulse of a reducing reactant 420. Loop 440 may be repeated until a certain thickness is reached, or in some embodiments, where the film (e.g., completely) fills the one or more features. In some embodiments, loop 440 is performed between about 10 and 100 times, or between about 15 and 30 times. Method 400 may deposit a film that is metallic. In some embodiments, method 400 comprises a cyclical deposition process.

A duration of providing the pulse of the reducing reactant to the reaction chamber during each cycle can be between about 0.1 seconds and about 60 seconds, between about 1 seconds and about 10 seconds, or between about 2 seconds and about 5 seconds. A flowrate of the reducing reactant to the reaction chamber can be less than 1000 sccm, or less than 500 sccm, or less than 100 sccm, or less than 10 sccm, or even less than 1 sccm or range from about 1 to 2000 sccm, from about 5 to 1000 sccm, or from about 10 to 500 sccm.

A duration of providing the pulse of the halide precursor to the reaction chamber during each cycle can be between about 0.1 seconds and about 3 seconds, between about 0.4 seconds and about 1 seconds, or between about 0.5 seconds and about 0.9 seconds. A flowrate of the halide precursor to the reaction chamber can be less than 1000 sccm, or less than 500 sccm, or less than 100 sccm, or less than 10 sccm, or even less than 1 sccm or range from about 1 to 2000 sccm, from about 5 to 1000 sccm, or from about 10 to 500 sccm.

The reducing reactant may be any suitable reactant that may reduce a component of the halide precursor. By way of examples, the reducing reactant may be or include a hydrogen-containing gas, such as hydrogen (H₂) or ammonia.

In some embodiments, the halide precursor comprises a metal. In some embodiments, the halide precursor comprises molybdenum. In some embodiments, the halide precursor comprises a metal halide. In some embodiments, the halide precursor comprises one or more metals and one or more halides. By way of examples, the halide precursor may be or include molybdenum chloride (MoCl₅).

One or more halide components of the halide precursor may react with a boron component of the growth promotion layer. Halide components may react with boron components to form volatile a boron halide compound that may be removed from the reaction chamber during a subsequent purge. As such, the growth promotion layer may be at least partially removed during the step of depositing the film. In some embodiments, the growth promotion layer may be removed such that the film is disposed directly on the metal surface. Not to be bound by theory, it is thought that the halide component of the halide precursor preferentially reacts with boron components of the growth promotion layer and not with the underlying metal surface. As such, the growth promotion layer may also act to passivate the underlying metal surface, while promoting growth of the film on the metal surface.

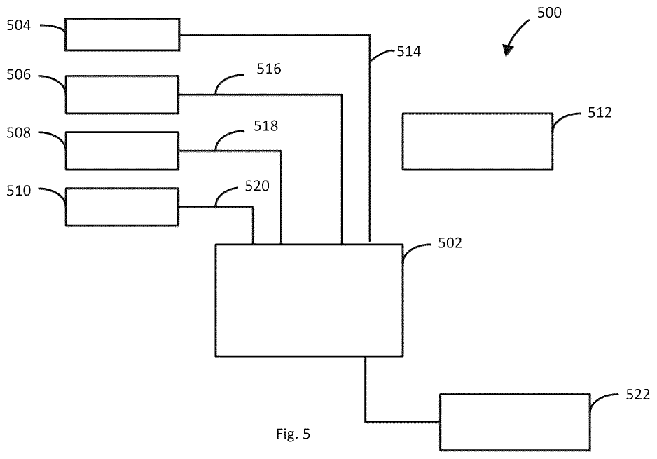

FIG. 5 illustrates an example of a substrate processing apparatus 500 in accordance with one or more examples of the disclosure. Apparatus 500 can be used to perform a method as described herein and/or form a structure or device portion as described herein.

In the illustrated example, apparatus 500 includes one or more reaction chambers 502, a boron-containing precursor gas source 504, a halide precursor gas source 506, a reducing reactant gas source 508, an inert gas source 510, an exhaust source 522, and a controller 512.

Reaction chamber 502 can include any suitable reaction chamber, such as an atomic layer deposition (ALD) or chemical vapor deposition (CVD) reaction chamber.

Boron-containing precursor gas source 504 can include a vessel and one or more boron-containing precursors as described herein-alone or mixed with one or more carrier (e.g., inert) gases. Halide precursor gas source 506 can include a vessel and one or more halide precursors as described herein-alone or mixed with one or more carrier (e.g., inert) gases. Reducing reactant gas source 508 can include a vessel and one or more of reducing reactants as described herein-alone or mixed with one and/or more carrier gases. Inert gas source 510 can include a vessel and one and/or more inert gases, such as nitrogen, helium, or argon. Although illustrated with four gas sources 504-510, apparatus 500 can include any suitable number of gas sources. Gas sources 504-510 can be coupled to reaction chamber 502 via lines 514-520, which can each include flow controllers, valves, heaters, and the like.

Exhaust source 522 can include one or more vacuum pumps.

Controller 512 includes electronic circuitry and software to selectively operate valves, manifolds, heaters, pumps, and other components included in the apparatus 500. Such circuitry and components operate to introduce precursors, reactants, and gases from the respective sources 504-510. Controller 512 can control timing of gas pulse sequences, temperature of the substrate and/or reaction chamber, pressure within the reaction chamber, and various other operations to provide proper operation of the apparatus 500. Controller 512 can include control software to electrically or pneumatically control valves to control flow of precursors, reactants, and purge gases into and out of the reaction chamber 502. Controller 512 can include modules such as a software or hardware component, e.g., a FPGA or ASIC, which performs certain tasks. A module can advantageously be configured to reside on the addressable storage medium of the control system and be configured to execute one or more processes or methods, as described herein.

Other configurations of apparatus 500 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into reaction chamber 502. Further, as a schematic representation of a system, many components have been omitted for simplicity of illustration, and such components may include, for example, various valves, manifolds, purifiers, heaters, containers, vents, and/or bypasses.

During operation of apparatus 500, substrates, such as semiconductor wafers (not illustrated), are transferred from, e.g., a substrate handling system to reaction chamber 502. Once substrate(s) are transferred to reaction chamber 502, one or more gases from gas sources 504-510, such as precursors, reactants, carrier gases, and/or purge gases, are introduced into reaction chamber 502.

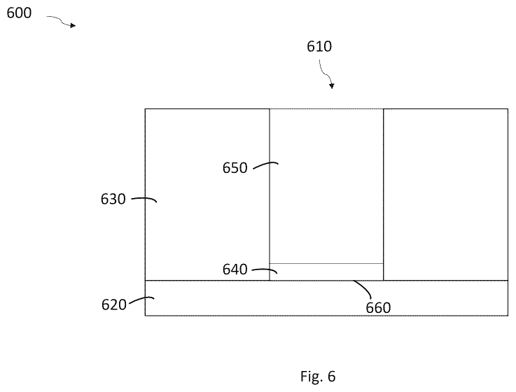

FIG. 6 illustrates a structure/a portion of a device 600 in accordance with additional examples of the disclosure. Device or structure 600 includes a substrate 620, a dielectric layer 630, a growth promotion layer 640, and a film 650. The growth promotion layer 640 and the film 650 may be disposed in a feature 610. The feature 610 may be a feature as described herein. The substrate 620 may comprise a metal surface 660. The metal surface 660 may comprise copper or cobalt. The growth promotion layer 640 may be formed by a method described in this disclosure. The growth promotion layer 640 may comprise boron. The growth promotion layer 640 may have a thickness between about 5 Angstroms and about 60 Angstroms, or between about 10 Angstroms and about 50 Angstroms, or between about 20 Angstroms and about 40 Angstroms. The film 650 may be formed by a method described in this disclosure. The film 650 may comprise metal. In some embodiments, the film 650 is metallic. In some embodiments, the film 650 is or includes an elemental metal or a metal alloy. In some embodiments, the film comprises molybdenum or copper. The film 650 may have a thickness between about 10 Angstroms to 100 Angstroms.

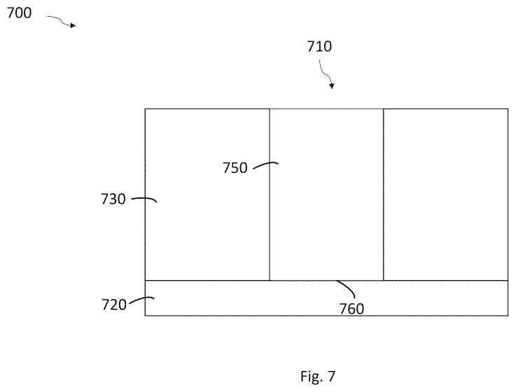

FIG. 7 illustrates a structure/a portion of a device 700 in accordance with additional examples of the disclosure. Device or structure 700 includes a substrate 720, a dielectric layer 730, and a film 750. The film 750 may be disposed in a feature 710. The feature 710 may be a feature as described herein. The substrate 720 may comprise a metal surface 760. The metal surface 760 may comprise copper or cobalt. The film 750 may be formed by a method described in this disclosure. The film 750 may comprise metal. In some embodiments, the film 750 is metallic. In some embodiments, the film 750 is or includes an elemental metal or a metal alloy. In some embodiments, the film 750 comprises molybdenum or copper. The film 750 may have a thickness between about 10 Angstroms to 100 Angstroms, or between about 20 Angstroms and about 70 Angstroms. Device or structure 700 may be substantially identical to device or structure 600 except device or structure 700 does not comprise a growth promotion layer. Film 750 is disposed directly on substrate 720.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method for forming a structure, the method comprising:
providing a substrate in a reaction chamber, wherein the substrate comprises a metal surface on at least part of a surface of the substrate;
performing a growth promotion treatment, wherein the growth promotion treatment comprises pulsing a boron-containing precursor to the reaction chamber and performing a purge; and
selectively depositing a film on the metal surface, wherein depositing the film comprises providing a halide precursor to the reaction chamber.

2. The method of claim 1, wherein the metal surface comprises one or more of copper, cobalt, nickel, zinc, ruthenium, or molybdenum.

3. The method of claim 1, wherein the metal surface is metallic.

4. The method of claim 1, wherein the boron-containing precursor comprises one or more of borane, diborane, triborane, triethylborane, trimethylborane, borazine, and borazane.

5. The method of claim 1, further comprising performing a pre-treatment process before performing the growth promotion treatment, wherein the pre-treatment process comprises generating a hydrogen plasma.

6. The method of claim 1, further comprising forming a growth promotion layer on the metal surface, wherein forming the growth promotion layer comprises pulsing the boron-containing precursor.

7. The method of claim 6, wherein the growth promotion layer has a thickness of between about 20 Angstroms and 50 Angstroms.

8. The method of claim 1, wherein the growth promotion treatment comprises repeating the steps of pulsing the boron-containing precursor to the reaction chamber and performing the purge a plurality of times.

9. The method of claim 1, wherein a temperature of the reaction chamber during the method is 400° C. or less.

10. The method of claim 1, wherein the film is metallic.

11. The method of claim 10, wherein depositing the film comprises providing a reducing reactant to the reaction chamber.

12. The method of claim 1, wherein a pulse of the boron-containing precursor is between about 0.2 and 5 seconds.

13. The method of claim 1, wherein a pressure in the reaction chamber is between about 1 to about 50 Torr.

14. The method of claim 1, wherein the surface of the substrate comprises one or more features comprising a bottom and one or more sidewalls, wherein the metal surface is disposed on the bottom of the one or more features.

15. The method of claim 14, wherein the one or more sidewalls comprise a low-k material.

16. The method of claim 15, wherein the growth promotion treatment comprises forming a growth promotion layer selectively on the metal surface, wherein forming the growth promotion layer comprises pulsing the boron-containing precursor.

17. The method of claim 6, wherein providing the halide precursor removes at least part of the growth promotion layer.

18. The method of claim 14, wherein the one or more features comprise an aspect ratio greater than 10.

19. The method of claim 1, wherein a temperature of the reaction chamber during the growth promotion treatment is 325° C. or less.

20. A method for depositing a film on a metal layer, the method comprising
providing a substrate in a reaction chamber, wherein the substrate comprises the metal layer on a surface of the substrate,
depositing a growth promotion layer directly on the metal layer, wherein depositing the growth promotion layer comprises pulsing a boron-containing precursor to the reaction chamber and performing a purge,
depositing the film directly on the growth promotion layer.
